(19) United States
(12) Patent Application Publication
(10) Pub. No.: US 2025/0212480 A1
(43) Pub. Date: Jun. 26, 2025

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventor: Yoshiki Endo, Kawasaki (JP)

(73) Assignees: KABUSHIKI KAISHA TOSHIBA, Tokyo (JP); Toshiba Electronic Devices & Storage Corporation, Tokyo (JP)

(21) Appl. No.: 19/076,255

(22) Filed: Mar. 11, 2025

Related U.S. Application Data
(63) Continuation of application No. PCT/JP2024/006799, filed on Feb. 26, 2024.

(30) Foreign Application Priority Data
Jul. 31, 2023 (JP) 2023-124352

(51) Int. Cl. H10D 64/23; H01L 23/00; H01L 23/49; H01L 25/07

(52) U.S. Cl. CPC H10D 64/231; H01L 23/49; H01L 24/05; H01L 25/072; H01L 2224/05017; H01L 2224/05557; H01L 2924/13055; H01L 2924/13091; H01L 2924/3512

(57) ABSTRACT

According to one embodiment, a semiconductor device includes a pellet; a first conductor and a second conductor sandwiching the pellet in a first direction; a first bonding material bonding the pellet and the first conductor; and a second bonding material bonding the pellet and the second conductor; wherein a first surface of the first conductor that faces the pellet includes a plurality of protrusions overlapping the pellet and a groove surrounding the pellet, when seen in the first direction, a design value of a height of the protrusions is a first value, and a volume of the groove is based on a volume of a part between the pellet and the first conductor, with a first height between the pellet and the first conductor having a second value larger than the first value.

### CROSS-REFERENCE TO RELATED APPLICATIONS

This application is a Continuation application of PCT Application No. PCT/JP2024/006799, filed Feb. 26, 2024 and based upon and claiming the benefit of priority from Japanese Patent Application No. 2023-124352, filed Jul. 31, 2023, the entire contents of all of which are incorporated herein by reference.

### FIELD

Embodiments described herein relate generally to a semiconductor device.

### BACKGROUND

A semiconductor device having a structure in which upper and lower surfaces of a pellet are coupled to a conductor via a bonding material has been known.

### BRIEF DESCRIPTION OF THE DRAWINGS

FIG. 1 is a perspective view showing an example of an exterior of a semiconductor device according to an embodiment.

FIG. 2 is an exploded view showing an example of an internal structure of the semiconductor device according to the embodiment.

FIG. 3 is a plan view showing an example of a planar layout of the semiconductor device according to the embodiment.

FIG. 4 is a sectional view taken along the line IV-IV indicated in FIG. 3, and shows an example of a sectional structure of the semiconductor device according to the embodiment.

FIG. 5 is a plan view showing an example of a planar layout of a semiconductor device according to a first modification.

FIG. 6 is a plan view showing an example of a planar layout of a semiconductor device according to a second modification.

FIG. 7 is a plan view showing an example of a planar layout of a semiconductor device according to a third modification.

### DETAILED DESCRIPTION

In general, according to one embodiment, a semiconductor device includes a pellet; a first conductor and a second conductor sandwiching the pellet in a first direction; a first bonding material bonding the pellet and the first conductor; and a second bonding material bonding the pellet and the second conductor; wherein a first surface of the first conductor that faces the pellet includes a plurality of protrusions overlapping the pellet and a groove surrounding the pellet, when seen in the first direction, a design value of a height of the protrusions is a first value, and a volume of the groove is based on a volume of a part between the pellet and the first conductor, with a first height between the pellet and the first conductor having a second value larger than the first value.

Hereinafter, an embodiment will be described with reference to the accompanying drawings. The dimensions and ratios in the drawings are not necessarily the same as the actual ones.

The description will use the same symbols for the components having substantially the same functions and configurations. When the components having the same or substantially the same configurations are to be distinguished from each other, different characters or numerals may be added to the same symbols.

### 1. EMBODIMENT

A semiconductor device according to an embodiment will be described.

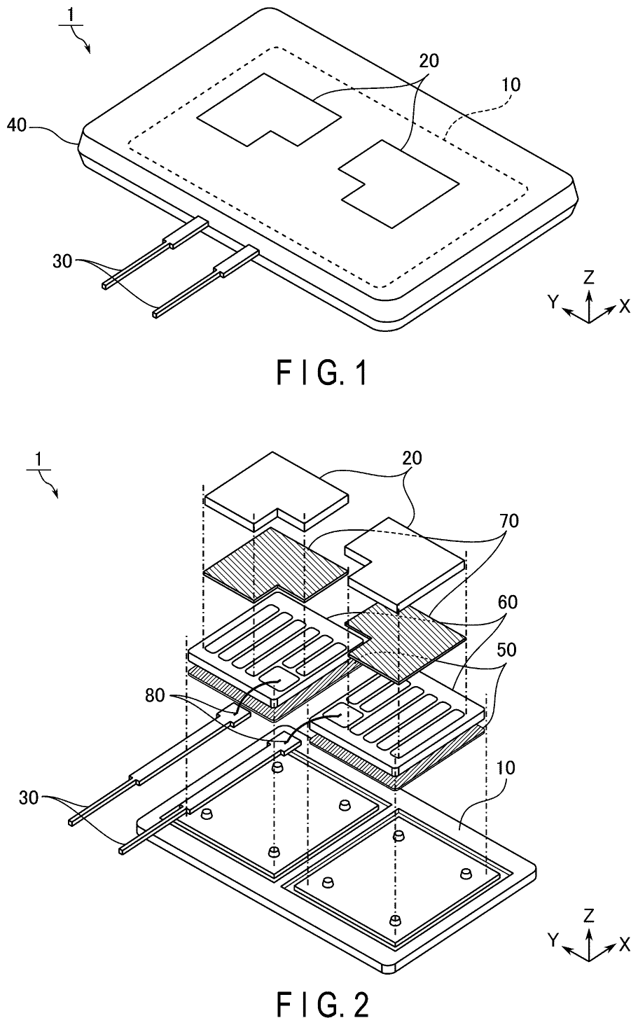

FIG. 1 is a perspective view showing an example of an exterior of the semiconductor device according to the embodiment. A semiconductor device 1 is an industrial power device. For example, the semiconductor device 1 has a shape of a thin cuboid. Hereinafter, the thickness direction of the semiconductor device 1 will be referred to as a top-to-bottom direction or a Z-direction. If the components of the semiconductor device 1 have two surfaces opposed to each other in the top-to-bottom direction, the two surfaces will be referred to as a lower surface and an upper surface, respectively. Two directions that are perpendicular to each other within a plane that is perpendicular to the Z-direction will be referred to an X-direction and a Y-direction, respectively.

The semiconductor device 1 includes a collector electrode 10, two emitter electrodes 20, two gate electrodes 30, and a sealing material 40. The collector electrode 10, the two emitter electrodes 20, and the two gate electrodes 30 each have a portion exposed to the outside of the sealing material 40 as a terminal for electrical coupling to the outside.

Each of the collector electrode 10 and the two emitter electrodes 20 is arranged so as to be exposed at the lower surface and the upper surface of the sealing material 40. For example, the exposed surface of the collector electrode 10 and the exposed surfaces of the two emitter electrodes 20 are flush with the lower surface and the upper surface of the sealing material 40. Seen in the thickness direction, the exposed surfaces of the two emitter electrodes 20 are included within the exposed surface of the collector electrode 10.

The two gate electrodes 30 are arranged so as to be exposed at the side surface of the sealing material 40. For example, the two gate electrodes 30 protrude from the side surface of the sealing material 40.

The sealing material 40 is an insulator that physically and electrically protects the internal structure of the semiconductor device 1 from the outside. The sealing material 40 forms the outer shape of the semiconductor device 1.

FIG. 2 is an exploded view showing an example of the internal structure of the semiconductor device according to the embodiment. FIG. 2 schematically shows the internal structure of the semiconductor device 1 exploded in the thickness direction. The illustration of the sealing material 40 is omitted in FIG. 2. As the internal structure, the semiconductor device 1 further includes two bonding materials 50, two pellets 60, two bonding materials 70, and two wires 80 in addition to the collector electrode 10, the two emitter electrodes 20, and the two gate electrodes 30.

Each of the collector electrode 10 and the emitter electrodes 20 is, for example, a copper plate having a thickness of about 1.5 mm. The lower surface of the collector electrode 10 corresponds to the surface of the collector electrode 10 exposed from the sealing material 40. For example, the lower surface of the collector electrode 10 is flat throughout the entire surface. A more specific configuration of the collector electrode 10 will be described later. The upper surfaces of the emitter electrodes 20 correspond to the surfaces of the emitter electrodes 20 exposed from the sealing material 40. For example, the upper surfaces of the emitter electrodes 20 are flat throughout the entire surface.

The two bonding materials 50 are arranged on the upper surface of the collector electrode 10 distantly from each other. The bonding materials 50 are, for example, plate-shaped solder. The bonding materials 50 are arranged between the collector electrode 10 and the pellets 60 corresponding thereto.

The pellets 60 are power semiconductor chips. Specifically, the pellets 60 are, for example, an insulated gate bipolar transistor (IGBT) or a metal-oxide-silicon field-effect transistor (MOSFET) that uses silicon carbide (SiC). If the pellets 60 are MOSFETs that use SiC, the collector electrode 10 and the emitter electrodes 20 will be read as a drain electrode and source electrodes, respectively.

The lower surfaces of the pellets 60 are used as electrodes corresponding to a collector. The lower surfaces of the pellets 60 are electrically coupled to the collector electrode 10 via the bonding materials 50. The lower surfaces of the pellets 60 have an area smaller than the area of the collector electrode 10. A pad corresponding to an emitter and a pad corresponding to a gate are arranged on each of the upper surfaces of the pellets 60. The upper surfaces of the pellets 60 have an area larger than the areas of the emitter electrodes 20.

The bonding materials 70 are arranged in the corresponding areas on the upper surfaces of the pellets 60 that include the pad corresponding to an emitter and exclude the pad corresponding to a gate. The bonding materials 70 are, for example, plate-shaped solder. The emitter electrodes 20 are arranged on the upper surfaces of the bonding materials 70 corresponding thereto.

An end of each of the wires 80 is arranged on the pads corresponding to a gate on the upper surfaces of the pellets 60 corresponding thereto. The wires 80 are bonding wires. The other end of each of the wires 80 is coupled to the gate electrodes 30 corresponding thereto.

For example, the two pellets 60 are arranged side by side in the Y-direction.

With the above-described configuration, three terminals used for input and output of the pellets 60 are respectively electrically coupled to the collector electrode 10, the emitter electrodes 20, and the gate electrodes 30 in the semiconductor device 1. The bonding materials 50 and 70 serve as electrical coupling between the pellets 60 and the terminals, and also function to release the heat generated in the pellets 60 in the top-to-bottom direction.

FIGS. 1 and 2 illustrate the case where two pellets 60 are provided in the semiconductor device 1; however, the embodiment is not limited thereto. One, or three or more pellets 60 may be provided in the semiconductor device 1.

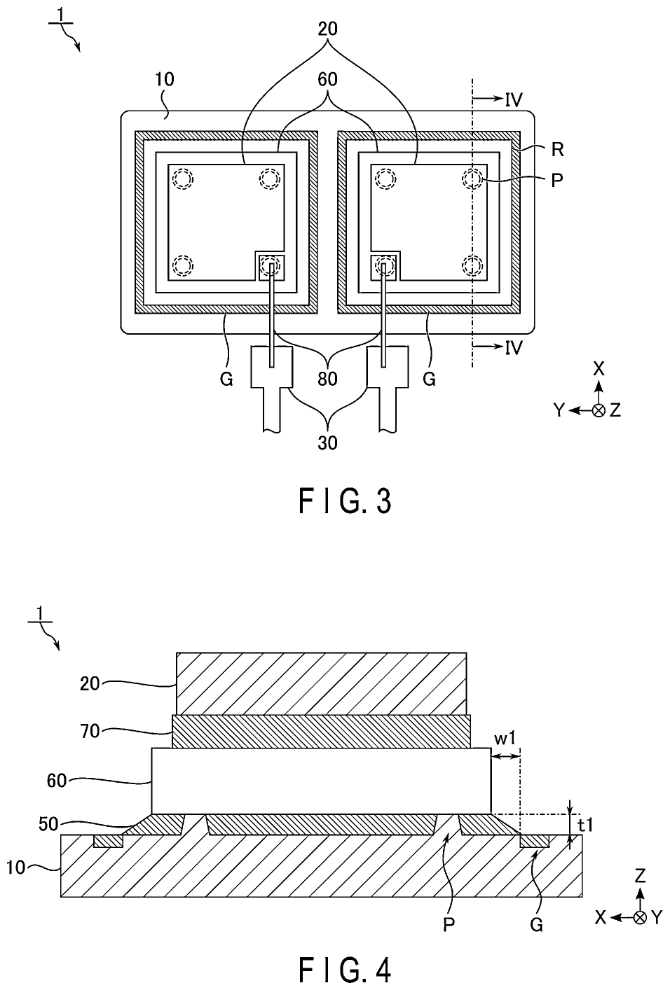

FIG. 3 is a plan view showing an example of a planar layout of the semiconductor device according to the embodiment. FIG. 4 is a sectional view taken along the line IV-IV indicated in FIG. 3, and shows an example of a sectional structure of the semiconductor device according to the embodiment. The illustration of the sealing material 40 is omitted in FIGS. 3 and 4.

For example, four collector protrusions P corresponding to each of the pellets 60 are provided to the upper surface of the collector electrode 10. That is, if the semiconductor device 1 includes two pellets 60, eight collector protrusions P are provided to the upper part of the collector electrode 10. Seen in the Z-direction, the collector protrusions P corresponding to each of the pellets 60 are provided so as to overlap the pellets 60. With the above-described configuration, each of the pellets 60 may come into contact with the upper surfaces of the four collector protrusions P. The number of collector protrusions P corresponding to each of the pellets 60 is not limited to four. It suffices that three or more collector protrusions P corresponding to each of the pellets 60 are provided.

Each of the collector protrusions P has a height t1 of, for example, 100 μm or more in the Z-direction. The collector protrusions P on the collector electrode 10 have variations, the height t1 of each of the collector protrusions P being deviated from a design value. That is, the height of each of the collector protrusions P has a value which is a minimum value or more and a maximum value or less. For example, if a design value of the height of the collector protrusions P is 150 μm and the height of each of the collector protrusions P varies in the range of ±20 μm with respect to the design value, the height of each of the collector protrusions P may be 130 μm or more and 170 μm or less. Also, if a design value is 200 μm and the height of each of the collector protrusions P varies in the range of ±20 μm with respect to the design value, for example, the height of each of the collector protrusions P may be 180 μm or more and 220 μm or less. For example, the maximum value and the minimum value of the height may be determined based on the design value and the processing precision.

The bonding materials 50 are arranged so as to fill the gap between the upper surface of the collector electrode 10 and the respective pellets 60 supported by the collector protrusions P. Thus, the bonding materials 50 have a thickness of, for example, 100 μm or more, as in the case of the height t1 of the collector protrusions P.

For example, two grooves G are provided in the upper part of the collector electrode 10. The respective grooves G are provided in association with the pellets 60. Thus, the two grooves G are, for example, arranged side by side in the Y-direction. The height of the upper surface of the collector electrode 10 excluding the collector protrusions P and the grooves G is, for example, at approximately the same level.

Seen in the Z-direction, each of the grooves G is, for example, arranged to surround a rectangular region R. The width in the Y-direction of the parts of the grooves G extending along the X-direction (i.e., the parts of the grooves G in contact with the side of the region R extending in the X-direction) and the width along the X-direction of the parts of the grooves G extending along the Y-direction (i.e., the parts of the grooves G in contact with the side of the region R extending in the Y-direction) are, for example, approximately the same. In the descriptions below, the width in the Y-direction of the parts of the grooves G extending along the X-direction and the width along the X-direction of the parts of the grooves G extending along the Y-direction will also be simply referred to as “the width of the grooves G.”

Seen in the Z-direction, each region R has an area larger than the area of the lower surfaces of the pellets 60. Seen in the Z-direction, the lower surfaces of the pellets 60 are respectively included in the regions R associated with the pellets 60. On one end side and the other end side of the pellets 60 in the X-direction, a width w1 between the pellets 60 and the grooves G is, for example, approximately 200 μm. Although not shown, on one end side and the other end side of the pellets 60 in the Y-direction, a width between the pellets 60 and the grooves G is also, for example, approximately 200 μm. With the above-described configuration, the collector protrusions P corresponding to each of the pellets 60 are provided inside the regions R associated with the pellets 60.

A part of the bonding materials 50 may be included inside the grooves G. To give supplementary information, the semiconductor device 1 configured as described above is formed by filling the gap between the collector electrode 10 and the pellets 60 with the bonding materials 50, filling the gap between the pellets 60 and the emitter electrodes 20 with the bonding materials 70, and then pressing the collection of the components in the top-to-bottom direction using a weight or the like (not shown). Thus, in this process, a force that pushes out the bonding materials 50 from between the pellets 60 and the collector electrode 10 acts on the bonding materials 50. The amount of the bonding materials 50 used to fill the gap between the collector electrode 10 and the pellets 60 is set such that, for example, the gap between the collector electrode 10 and the pellets 60 is filled when the height of all the collector protrusions P has a maximum value of the height of the collector protrusions P. Such a formation method may cause an excess amount of bonding materials 50 to flow out to the outside of the pellets 60 when seen in the Z-direction. Also, a part of the bonding materials 50 that has flowed out may be included inside the grooves G.

Taking into consideration that a portion of the bonding materials 50 that has flowed out is formed as described above, the grooves G are formed based on the volume of the part between the collector electrode 10 and the pellets 60 with the height of the collector protrusions P (and the height of the part sandwiched by the collector electrode 10 and the pellets 60) having a maximum value. More specifically, the grooves G are formed so as to have, for example, a volume equal to or greater than a volume obtained by subtracting the volume of the aforementioned part with the height of the collector protrusions P having a design value from the volume of the aforementioned part with the height of the collector protrusions P having a maximum value. In such a configuration of the grooves G, the volume of the grooves G may be based on, for example, an average value, a median, or the like of the heights of the collector protrusions P instead of the design value of the height of the collector protrusions P.

According to the embodiment, the grooves G arranged outside the pellets 60 and around the pellets 60, and the collector protrusions P arranged so as to overlap the pellets 60, are included in the upper part of the collector electrode 10, when seen from the upper side. The volume of the grooves G is based on the volume of the part between the collector electrode 10 and the pellets 60 with the height of the collector protrusions P having a maximum value. More specifically, the grooves G are formed so as to have a volume equal to or greater than a volume obtained by subtracting the volume of the aforementioned part between the collector electrode 10 and the pellets 60 with the height of the collector protrusions P having a reference value from the volume of the aforementioned part between the collector electrode 10 and the pellets 60 with the height of the collector protrusions P having a maximum value. With such a configuration as described above, even if solder flows out from between the collector electrode 10 and the pellets 60 when pressed in the top-to-bottom direction in the manufacturing process, it is possible to suppress an outflow of the solder to the outside of the grooves G. This makes it possible to suppress an excess spread of the solder on the upper surface of the collector electrode 10. Thus, the solder that has not bonded to the sealing material 40 spreads on the upper surface of the collector electrode, thereby suppressing the likelihood of the sealing material 40 being peeled off. Accordingly, the degradation of the reliability of the semiconductor device 1 can be suppressed.

### 2. MODIFICATIONS

Semiconductor devices according to modifications will be described next. Mainly the configurations of the semiconductor devices according to the modifications that differ from the configurations of the semiconductor device according to the foregoing embodiment will be explained. A description of a configuration comparable to that of the foregoing embodiment will be omitted as appropriate.

### 2.1. First Modification

A first modification differs from the foregoing embodiment in that the grooves include a part having a width larger than the width of the other parts, when seen in the Z-direction.

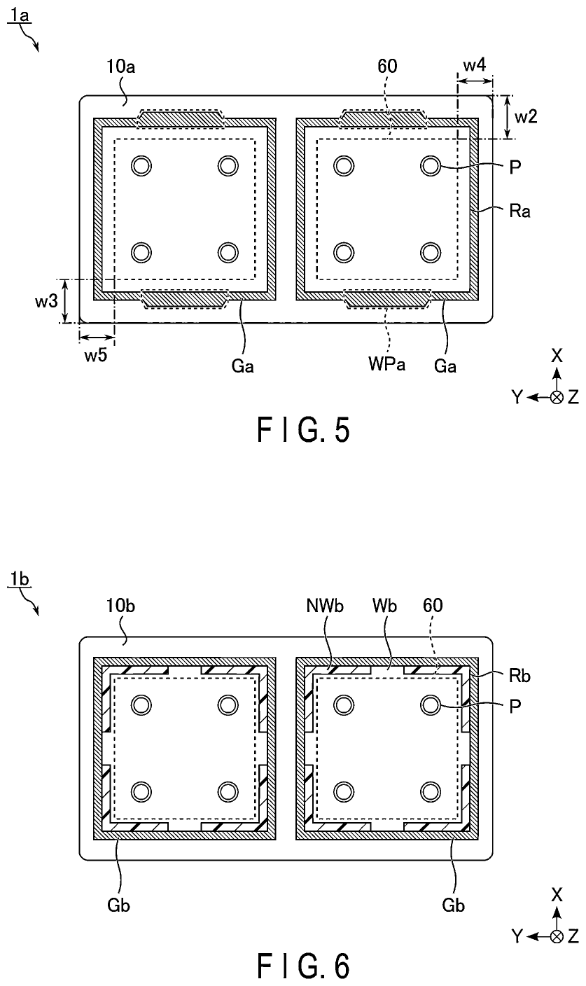

FIG. 5 is a plan view showing an example of a planar layout of a semiconductor device according to the first modification. FIG. 5 corresponds to FIG. 3. The illustration of the emitter electrodes 20, the gate electrodes 30, and the wires 80 is omitted in FIG. 5. Also, in FIG. 5, the regions where the pellets 60 are arranged are shown as dotted lines.

In a semiconductor device 1a according to the first modification, a first part of the collector electrode 10 on one end side with respect to the pellets 60 in the X-direction has a width w2. The first part is a part between one end of the pellets 60 and a side of the collector electrode 10 on one end side in the X-direction. A second part of the collector electrode 10 on the other end side with respect to the pellets 60 in the X-direction has a width w3. The second part is a part between the other end of the pellets 60 and a side of the collector electrode 10 on the other end side in the X-direction. A third part of the collector electrode 10 on one end side with respect to the pellet 60 on one end side out of the two pellets 60 in the Y-direction has a width w4. The third part is a part between one end of said pellet 60 on one end side and a side of the collector electrode 10 on one end side in the Y-direction. A fourth part of the collector electrode 10 on the other end side with respect to the pellet 60 on the other end side out of the two pellets 60 in the Y-direction has a width w5. The fourth part is a part between the other end of said pellet 60 on the other end side and a side of the collector electrode 10 on the other end side in the Y-direction. For example, the widths w2 and w3 are larger than the widths w4 and w5.

The parts of grooves Ga extending along the Y-direction include, for example, parts WPa whose width is larger than the widths of the other parts of the grooves Ga. That is, the grooves Ga include the parts WPa having a large width in the first part and the second part each having a width larger than the widths of the third part and the fourth part. The widths of the grooves Ga in the other parts except the parts WPa are, for example, equal. In the example shown in FIG. 5, each of the grooves Ga has two parts WPa. However, the configuration is not limited thereto. Each of the grooves Ga may have one, or three or more parts WPa.

In the above descriptions, the first part, the second part, the third part, and the fourth part may be a part of the collector electrode 10 on one end side with respect to regions Ra on the inner side of the grooves Ga in the X-direction, a part of the collector electrode 10 on the other end side with respect to the regions Ra in the X-direction, a part of the collector electrode 10 on one end side with respect to the region Ra on one end side out of the two regions Ra in the Y direction, and a part of the collector electrode 10 on the other end side with respect to the region Ra on the other end side out of the two regions Ra in the Y direction, respectively. In this case, the first part, the second part, the third part, and the fourth part are a part between the sides of the regions Ra on one end side and the side of the collector electrode 10 on one end side in the X-direction, a part between the sides of the regions Ra on the other end side and the side of the collector electrode 10 on the other end side in the X-direction, a part between one end of said region Ra on one end side and the side of the collector electrode 10 on one end side in the Y-direction, and a part between the other end of said region Ra on the other end side and the side of the collector electrode 10 on the other end side in the Y-direction, respectively.

The first modification also produces effects that are comparable to the effects of the foregoing embodiment.

Also, the grooves Ga include the parts WPa having a large width in the first part and the second part each having a width larger than the widths of the third part and the fourth part. Thus, it is possible to secure a part of the collector electrode 10a that is bonded to the sealing material 40 in a region on the outer side of the grooves Ga while suppressing an increase in the size of the semiconductor device 1a. To give supplementary information, if, for example, the grooves include a part having a width larger than the widths of the other parts of the grooves in the third part and the fourth part having a width smaller than the widths of the first part and the second part, it may not be possible to sufficiently secure a part of the collector electrode that is bonded to the sealing material in a region outside the grooves. According to the first modification, the above-described configuration makes it possible to secure a part of the collector electrode that is bonded to the sealing material without increasing the size of the collector electrode or the size of the semiconductor device.

### 2.2. Second Modification

The second modification differs from the foregoing embodiment in that the collector electrode has a non-wet region.

FIG. 6 is a plan view showing an example of a planar layout of a semiconductor device according to the second modification. FIG. 6 corresponds to FIGS. 3 and 5. The illustration of the emitter electrodes 20, the gate electrodes 30, and the wires 80 is omitted in FIG. 6, as in FIG. 5. Also, in FIG. 6, the regions where the pellets 60 are arranged are shown in dotted lines, as in FIG. 5.

A semiconductor device 1b according to the second modification has a non-wet region NWb in a region Rb on the side further inward than a groove Gb of the collector electrode 10b. Solder is less likely to flow into the non-wet region NWb, and it is difficult to provide solder in the non-wet region NWb. The non-wet region NWb is formed by performing resist coating, oxidation treatment using a laser, or the like. The non-wet region NWb is partially arranged on an outer periphery in the region Rb on the side further inward than the groove Gb. In the descriptions below, the region in the region Rb without the non-wet region NWb will be referred to as a wet region Wb.

The wet region Wb is arranged so as to be in contact with the groove Gb. In the example shown in FIG. 6, the wet region Wb is arranged so as to be in contact with two parts of the groove Gb that extend along the X-direction and two parts of the groove Gb that extend along the Y-direction. It suffices that the non-wet region NWb and the wet region Wb that is in contact with the groove Gb are arranged on the outer periphery in the region Rb on the side further inward than the groove Gb, and the number of portions where the wet region Wb is in contact with the groove Gb is not limited to four. The wet region Wb may be in contact with the groove Gb at one to three portions or five or more portions.

The second modification also produces effects that are comparable to the effects of the foregoing embodiment.

According to the second modification, the non-wet region NWb and the wet region Wb that is in contact with the groove Gb are arranged on the outer periphery in the region Rb on the side further inward than the groove Gb. Thus, it is possible to limit the areas where solder flows out from between the collector electrode 10 and the pellets 60 in the manufacturing process. As a result, it is possible to suppress an excess outflow of the solder from between the collector electrode 10 and the pellets 60. Accordingly, it is possible to suppress generation of a shrinkage cavity (crack, etc.) in the solder.

### 2.3. Third Modification

The third modification differs from the first modification in that the collector electrode has a non-wet region.

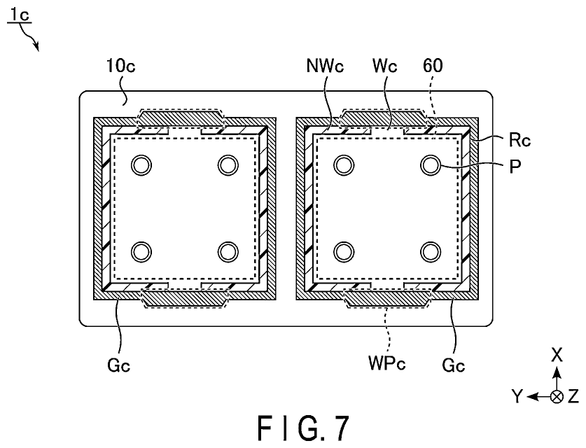

FIG. 7 is a plan view showing an example of a planar layout of a semiconductor device according to the third modification. FIG. 7 corresponds to FIGS. 3, 5, and 6. The illustration of the emitter electrodes 20, the gate electrodes 30, and the wires 80 is omitted in FIG. 7, as in FIGS. 5 and 6. Also, in FIG. 7, the regions where the pellets 60 are arranged are shown in dotted lines, as in FIGS. 5 and 6.

In a semiconductor device 1c according to the third modification, a part WPc of a groove Gc having a large width, like the parts WPa of the grooves Ga of the first modification, is arranged in the first part and the second part having a width larger than the widths of the third part and the fourth part. That is, the part WPc having a large width is included in the part of the groove Gc that extends along the Y-direction.

In the semiconductor device 1c according to the third modification, a non-wet region NWc is partially arranged on an outer periphery of a region Rc on the side further inward than the groove Gc, as in the non-wet region NWb of the second modification. Also, a wet region Wc is arranged so as to be in contact with the groove Gc. In the third modification, the wet region Wc is arranged in association with the part WPc having a large width. More specifically, each of the wet regions Wc is in contact with the part WPc corresponding thereto. The length of each of the wet regions Wc along the Y-direction is, for example, shorter than the length of the corresponding part WPc having a large width in the Y-direction. Seen in the X-direction, each of the wet regions Wc is arranged so as to overlap the corresponding part WPc having a large width. In such a configuration as described above, the non-wet region NWc is arranged in the entire region on the outer periphery of the region Rc except in the wet region Wc in contact with the part WPc.

The third modification produces effects that are comparable to the effects of the foregoing embodiment, the first modification, and the second modification.

Also, according to the third modification, the wet region Wc is arranged so as to be in contact with the corresponding part WPc having a large width. Thus, in the manufacturing process, solder is more likely to flow out from between the collector electrode 10 and the pellets 60 to the part WPc having a large width through the portion of the wet region Wc that is in contact with the groove Gc. Even with such a configuration, it is possible to suppress the outflow of the solder from between the collector electrode 10 and the pellets 60 to the outside of the groove Gc in the manufacturing process.

### 3. OTHERS

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a pellet;
a first conductor and a second conductor sandwiching the pellet in a first direction;
a first bonding material bonding the pellet and the first conductor; and
a second bonding material bonding the pellet and the second conductor;
wherein
a first surface of the first conductor that faces the pellet includes a plurality of protrusions overlapping the pellet and a groove surrounding the pellet, when seen in the first direction,
a design value of a height of the protrusions is a first value, and
a volume of the groove is based on a volume of a part between the pellet and the first conductor, with a first height between the pellet and the first conductor having a second value larger than the first value.

2. The semiconductor device according to claim 1, wherein the volume of the groove is equal to or greater than a volume obtained by subtracting a volume of the part between the pellet and the first conductor with the first height having the first value from the volume of the part between the pellet and the first conductor with the first height having the second value.

3. The semiconductor device according to claim 1, wherein the second value is a maximum value among varying values of the height of the protrusions.

4. The semiconductor device according to claim 1, wherein three or more of the protrusions are provided.

5. The semiconductor device according to claim 1, wherein
the first conductor has a first part outside the pellet, and a width of the first part is a first width,
the first conductor has a second part outside the pellet and different from the first part, and a width of the second part is a second width smaller than the first width, and
the groove of the first conductor includes a first groove portion in the first part, the first groove portion having a width larger than a width of the groove in the second part.

6. The semiconductor device according to claim 1, wherein, in a region on an inner side of the groove of the first conductor, a non-wet region partially arranged on an outer periphery and a wet region in contact with the groove are arranged, when seen in the first direction.

7. The semiconductor device according to claim 6, wherein the non-wet region is a region obtained by performing resist coating or oxidation treatment.

8. The semiconductor device according to claim 5, wherein, in a region on an inner side of the groove of the first conductor, a non-wet region partially arranged on an outer periphery and a wet region in contact with the first groove portion are arranged, when seen in the first direction.

9. The semiconductor device according to claim 8, wherein the non-wet region is arranged in an entire region on the outer periphery excluding the wet region.

10. The semiconductor device according to claim 1, wherein the first bonding material and the second bonding material include solder.

11. The semiconductor device according to claim 1, wherein
the pellet, the first bonding material, and the second bonding material are sealed by a sealing material, and
each of the first conductor and the second conductor includes at least a part exposed from the sealing material.
